(19) United States
(12) Patent Application Publication
(10) Pub. No.: US 2025/0299944 A1
(43) Pub. Date: Sep. 25, 2025

(54) ELECTRON-WITHDRAWING FUNCTIONAL GROUPS ON SI-CHALCOGEN PRECURSORS

(71) Applicants: Applied Materials, Inc., Santa Clara, CA (US); National University of Singapore, Singapore (SG)

(72) Inventors: Zhijie Chua, Singapore (SG); Chandan Kr Barik, Singapore (SG); John Sudijono, Singapore (SG); Bhaskar Jyoti Bhuyan, San Jose, CA (US); Michael Haverty, Mountain View, CA (US); Muthukumar Kaliappan, Fremont, CA (US); Sao Chuan Yeh, Singapore (SG); Anil Kumar Tummanapelli, Singapore (SG); Yingqian Chen, Singapore (SG); Richard Ming Wah Wong, Singapore (SG)

(73) Assignees: Applied Materials, Inc., Santa Clara, CA (US); National University of Singapore, Singapore (SG)

(21) Appl. No.: 18/609,273

(22) Filed: Mar. 19, 2024

(51) Int. Cl. H01L 21/02; C23C 16/34; C23C 16/40; C23C 16/455

(52) U.S. Cl. CPC H01L 21/02211; C23C 16/345; C23C 16/401; C23C 16/45527; C23C 16/45553; H01L 21/0214; H01L 21/02164; H01L 21/0217

(57) ABSTRACT

Chalcogen silane precursors having electron withdrawing groups are described. Methods for depositing one or more of a silicon nitride (SiₓN_{y}) film, a silicon oxide (SiOₓ) film, or a silicon oxynitride (SiOₓN_{z}) on a substrate are described. The substrate is exposed to the chalcogen silane precursor and a reactant to deposit the silicon nitride (SiₓN_{y}) film, the silicon oxide (SiOₓ) film, and/or the silicon oxynitride (SiOₓN_{z}) film. The exposures can be sequential or simultaneous. The chalcogen silane may be substantially free of halogen. The chalcogen may be selected from the group consisting of sulfur (S), selenium (Se), and tellurium (Te).

### TECHNICAL FIELD

Embodiments of the disclosure relate to silicon-chalcogen precursors and methods for depositing silicon- and chalcogen-containing films. More particularly, embodiments of the disclosure are directed to silicon-chalcogen precursors containing an electron withdrawing group and a chalcogen and methods of depositing said precursors to form silicon nitride, silicon oxide, and/or silicon oxynitride films.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

The advancing complexity of advanced microelectronic devices is placing stringent demands on currently used deposition techniques. Unfortunately, there are a limited number of viable chemical precursors available that have the requisite properties of robust thermal stability, high reactivity, and vapor pressure suitable for film growth to occur. In addition, precursors that often meet these requirements still suffer from poor long-term stability and lead to thin films that contain elevated concentrations of contaminants such as oxygen, nitrogen, and/or halides that are often deleterious to the target film application.

Silicon nitride (SiₓN_{y}) films and silicon oxide (SiOₓ) films have attractive material and conductive properties for semiconductor devices. These films have been proposed and tested for applications from front-end to back-end parts of semiconductor and microelectronic devices. Most of the current state-of-art approaches for atomic layer deposition of silicon nitride (SiₓN_{y}) films and silicon oxide (SiOₓ) films are based on silane precursors that contain direct Si-halogen coordination. The halogen contamination may affect device performance and hence require additional removal procedures. Also, sometimes, halogen removal requires higher thermal budget. The uses of high temperature processes are not desirable for temperature-sensitive substrates (e.g., logic devices). There is, therefore, a need in the art for silane precursors that are free of halogen and that react to form silicon nitride (SiₓN_{y}) films, silicon oxide (SiOₓ) films, and/or silicon oxynitride (SiOₓN_{z}) films at lower temperature.

### SUMMARY

One or more embodiments of the disclosure are directed to a method of depositing a film. In one or more embodiments, the method comprises: exposing a substrate to a silicon-chalcogen precursor comprising a chalcogen and an electron withdrawing group; and exposing the substrate to a reactant to form a silicon nitride (SiₓN_{y}) film, a silicon oxide (SiOₓ) film, or a silicon oxynitride (SiOₓN_{z}) film on the substrate.

Other embodiments are directed to methods of depositing halogen-free films. In one or more embodiments, the method comprises: forming one or more of a silicon nitride (SiₓN_{y}) film, a silicon oxide (SiOₓ) film, or a silicon oxynitride (SiOₓN_{z}) film in a process cycle comprising sequential exposure of a substrate to a silicon-chalcogen precursor, purge gas, reactant, and purge gas, the silicon-chalcogen precursor comprising a chalcogen and an electron withdrawing group.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Embodiments of the disclosure provide precursors and processes for depositing silicon nitride (SiₓN_{y}) films, silicon oxide (SiOₓ), and/or silicon oxynitride (SiOₓN_{z}) films. The precursor comprises a silicon-chalcogen (Si-chalcogen) precursor. In one or more embodiments, the silicon-chalcogen precursor comprises a quaternary chalcogen silane. In some embodiments, the silicon-chalcogen precursor comprises a silane having one or more chalcogens or derivatives thereof and one or more electron withdrawing group. In some embodiments, the chalcogen is selected from the group consisting of sulfur (S), selenium (Se), and tellurium (Te).

In some embodiments, the silicon-chalcogen precursor is substantially free of silicon-halogen direct coordination. As used herein, the term “substantially free” means that there is less than about 5%, including less than about 4%, less than about 3%, less than about 2%, less than about 1%, and less than about 0.5% of silicon-halogen direct coordination, on an atomic basis, in the quaternary chalcogen silane.

In one or more embodiments, the silicon-chalcogen precursor is used to deposit silicon nitride (SiₓN_{y}) films, silicon oxide (SiOₓ) films, and/or silicon oxynitride (SiOₓN_{z}) films under ALD and CVD conditions. The process of various embodiments uses vapor deposition techniques, such as an atomic layer deposition (ALD) or chemical vapor deposition (CVD). The silicon-chalcogen precursors of one or more embodiments are volatile and thermally stable, and, thus, suitable for vapor deposition.

In one or more embodiments, the silicon-chalcogen precursor has a thermal stability at a temperature in a range of from 50° C. to 500° C., from 50° C. to 400° C., from 50° C. to 300° C., from 50° C. to 200° C., from 50° C. to 100° C., from 100° C. to 500° C., from 100° C. to 400° C. from 100° C. to 300° C. from 100° C. to 200° C., from 200° C. to 500° C., from 200° C. to 400° C. or from 200° C. to 300° C.

In one or more embodiments, the silicon-chalcogen precursor reacts with one or more of ammonia (NH₃), amines, hydrazine, oxidants, or water (H₂O) at a temperature in a range of from 15° C. to 100° C., from 20° C. to 100° C. or from 25° C. to 100° C. In some embodiments, the silicon-chalcogen precursor reacts with one or more of ammonia (NH₃), amines, hydrazine, oxidants, or water (H₂O) at room temperature. As used herein, the term “room temperature” refers to a temperature in a range of from 15° C. to 30° C. In some embodiments, the silicon-chalcogen precursor spontaneously reacts with amines at a temperature in a range of from 15° C. to 100° C., from 20° C. to 100° C. or from 25° C. to 100° C.

The silicon-chalcogen precursors of one or more embodiments are substantially free of halogen. In some embodiments, the use of silicon-chalcogen precursors that are substantially free of halogen provides silicon nitride (SiₓN_{y}) films, silicon oxide (SiOₓ) films, and/or silicon oxynitride (SiOₓN_{z}) films that are substantially free of halogen. As used herein, the term “substantially free” means that there is less than about 5%, including less than about 4%, less than about 3%, less than about 2%, less than about 1%, and less than about 0.5% of halogen on an atomic basis in the silicon nitride (SiₓN_{y}) films, silicon oxide (SiOₓ) films, and/or silicon oxynitride (SiOₓN_{z}) films.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Without intending to be bound by theory, it is thought that the presence of halogens in the structure of the precursors can pose challenges, as halogen contamination may affect device performance and hence require additional removal procedures. Additionally, in one or more embodiments, it was advantageously found that the presence of an electron withdrawing group increase the reactivity of the silicon-chalcogen precursor when compared to silicon-chalcogen precursors that do not contain electron withdrawing groups.

Silicon nitride (SiₓN_{y}) films, silicon oxide (SiOₓ) films, and/or silicon oxynitride (SiOₓN_{z}) films can be grown by atomic layer deposition or chemical vapor deposition for many applications. One or more embodiments of the disclosure advantageously provide processes for atomic layer deposition or chemical vapor deposition to form silicon nitride (SiₓN_{y}) films, silicon oxide (SiOₓ) films, and/or silicon oxynitride (SiOₓN_{z}) films.

The skilled artisan will recognize that the use of a molecular formula like SiₓN_{y} and SiOₓ does not imply a specific stoichiometric relationship between the elements but merely the identity of the major components of the film. For example, SiₓN_{y} refers to a film whose major composition comprises silicon and nitrogen atom, and SiOₓ refers to a film whose major composition comprises silicon and oxygen atoms. In some embodiments, the major composition of the specified film (i.e., the sum of the atomic percent of the specified atoms) is greater than or equal to about 95%, 98%, 99% or 99.5% of the film, on an atomic basis.

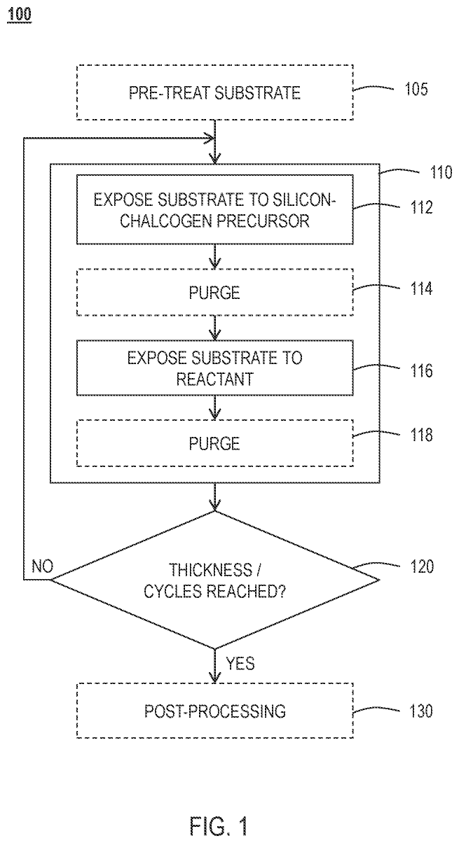

With reference to FIG. 1, one or more embodiments of the disclosure are directed to method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In some embodiments, the method 100 includes a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 105.

At deposition 110, a process is performed to deposit a silicon nitride (SiₓN_{y}) film on the substrate (or substrate surface). The deposition process can include one or more operations to form a silicon nitride (SiₓN_{y}) film, a silicon oxide (SiOₓ) film, and/or a silicon oxynitride (SiOₓN_{z}) film on the substrate. In operation 112, the substrate (or substrate surface) is exposed to a silicon-chalcogen precursor to deposit a precursor film on the substrate (or substrate surface). The silicon-chalcogen precursor can be any suitable silicon- and chalcogen-containing compound that can react with (i.e., adsorb or chemisorb onto) the substrate surface to leave a silicon nitride species on the substrate surface.

Current silane precursors for ALD of silicon nitride (SiₓN_{y}) films use halogen substituents, which often require high process temperature in order to remove the halogen containing side products and contaminants. Accordingly, one or more embodiments use the one or more silicon-chalcogen precursors or derivatives thereof. In some embodiments, the silicon-chalcogen precursors or derivatives thereof are substantially free of silicon-halogen coordination. In some embodiments, the silicon-chalcogen precursors comprise less than about 5%, including less than about 4%, less than about 3%, less than about 2%, less than about 1%, and less than about 0.5% of silicon-halogen coordination on an atomic basis. The silicon-chalcogen precursors comprise improved thermal stability, while retaining high volatility.

In one or more embodiments, the silicon-chalcogen precursor comprises a silane having one or more chalcogens or derivatives thereof and an electron withdrawing group. In one or more embodiments, the chalcogen is selected from the group consisting of sulfur (S), selenium (Se), and tellurium (Te). In one or more embodiments, the silicon-chalcogen precursor comprises one or more of a thiosilane, a selenosilane, and a tellurosilane.

In some embodiments, the silicon-chalcogen precursors has a structure according to general Formula (I)

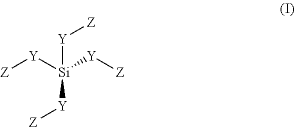

wherein Y is selected from the group consisting of oxygen (O), sulfur (S), selenium (Se), and tellurium (Te), and Z is an electron withdrawing group. In one or more embodiments, Z is selected from the group consisting of fluorinated or perfluoronated alkyl groups having the general formula (II) CₙF₂ₙ₊₁, wherein n is an integer in a range of from 1 to 10, fluorinated or perfluoronated alkyl groups having the general formula (III) CnH₂ₙCF₃, wherein n is an integer in a range of from 1 to 10, nitro (NO₂), nitroso (NO), nitrile (CN), and SO₂CF₃.

Unless otherwise indicated, the term “lower alkyl,” “alkyl,” or “alk” as used herein alone or as part of another group includes both straight and branched chain hydrocarbons, containing 1 to 20 carbons, or 1 to 10 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

In one or more embodiments, the silicon-chalcogen precursor comprises a chalcogen moiety. In some embodiments, the chalcogen moiety is selected from the group consisting of -MCₙF₂ₙ₊₁, wherein n is an integer in a range of from 1 to 10, MCₙH₂ₙCF₃, wherein n is an integer in a range of from 1 to 10, -MNO₂, -MCN, and MSO₂CF₃, wherein M is selected from the group consisting of oxygen (O), sulfur (S), selenium (Se), and tellurium (Te). In some embodiments, the chalcogen is substantially free of halogen. In some embodiments, the chalcogen moiety of the halogen free chalcogen is selected from the group consisting of -MCₙF₂ₙ₊₁, wherein n is an integer in a range of from 1 to 10, MCₙH₂ₙCF₃, wherein n is an integer in a range of from 1 to 10, -MNO₂, -MCN, and MSO₂CF₃, wherein M is selected from the group consisting of oxygen (O), sulfur (S), selenium (Se), and tellurium (Te).

In one or more embodiments, the silicon-chalcogen precursor comprises a silane having one or more thiol (—SH) or derivatives thereof. In one or more embodiments, the silicon-chalcogen precursor comprises one or more thiosilanes. In some embodiments, the chalcogen moiety is selected from the group consisting of —SCₙF₂ₙ₊₁, wherein n is an integer in a range of from 1 to 10, SCₙH₂ₙCF₃, wherein n is an integer in a range of from 1 to 10, —SNO₂, —SCN, and SSO₂CF₃. In some embodiments, the silicon-chalcogen precursor has a structure according to Formula (IV) Si(SCH₂CF₃)₄

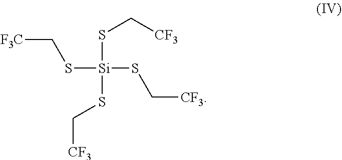 [SMILES: FC(F)(F)CS[Si](SCC(F)(F)F)(SCC(F)(F)F)SCC(F)(F)F]

In one or more embodiments, the silicon-chalcogen precursor comprises a silane having one or more oxygen or derivatives thereof. In one or more embodiments, the silicon-chalcogen precursor comprises oxysilane. In some embodiments, the chalcogen moiety is selected from the group consisting of —OCₙF₂ₙ₊₁, wherein n is an integer in a range of from 1 to 10, OCₙH₂ₙCF₃, wherein n is an integer in a range of from 1 to 10, —ONO₂, —OCN, and OSO₂CF₃. In some embodiments, the silicon-chalcogen precursor has a structure according to or Formula (V) Si(OSO₂CF₃)₄

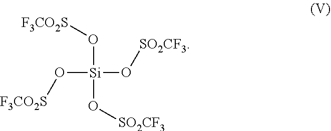

In one or more embodiments, the silicon-chalcogen precursor comprises a silane having one or more seleno (—SeH) or derivatives thereof. In one or more embodiments, the silicon-chalcogen precursor comprises one or more selenosilanes. In some embodiments, the chalcogen moiety is selected from the group consisting of —SeCₙF₂ₙ₊₁, wherein n is an integer in a range of from 1 to 10, SeCₙH₂ₙCF₃, wherein n is an integer in a range of from 1 to 10, —SeNO₂, —SeCN, and —SeSO₂CF₃.

In one or more embodiments, the silicon-chalcogen precursor comprises a silane having one or more telluro (—TeH) or derivatives thereof. In one or more embodiments, the silicon-chalcogen precursor comprises tellurosilane. In some embodiments, the chalcogen moiety is selected from the group consisting of —TeCₙF₂ₙ₊₁, wherein n is an integer in a range of from 1 to 10, TeCₙH₂ₙCF₃, wherein n is an integer in a range of from 1 to 10, —TeNO₂, —TeCN, and TeSO₂CF₃.

As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the silicon nitride (SiₓN_{y}) film, the silicon oxide (SiOₓ) film, and/or the silicon oxynitride (SiOₓN_{z}) film, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate. For example, in some embodiments, a layer comprising a metal, a nitride, an oxide, or the like, or combinations thereof may be disposed on the substrate and may have the silicon nitride (SiₓN_{y}) layer and/or the silicon oxide (SiOₓ) layer formed upon such layer or layers.

At operation 114, the processing chamber is optionally purged to remove unreacted silicon-chalcogen precursor, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the silicon-chalcogen precursor by any suitable technique including, but not limited to, moving the substrate through a gas curtain to a portion or sector of the processing chamber that contains none or substantially none of the silicon-chalcogen precursor. In some embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

At operation 116, the substrate (or substrate surface) is exposed to a reactant to form one or more of a silicon nitride (SiₓN_{y}) film and/or a silicon oxide (SiOₓ) film on the substrate. The reactant can react with the chalcogen-containing species on the substrate surface to form the silicon nitride (SiₓN_{y}) film. In other embodiments, the reactant can react with the chalcogen-containing species on the substrate surface to form the silicon oxide (SiOₓ) film. In some embodiments, the reactant comprises one or more of a reducing agent or an oxidizing agent. In one or more embodiments, the reducing agent can comprise any reducing agent known to one of skill in the art. In further embodiments, the reactant comprises one or more reducing agent. In one or more embodiments, the oxidizing agent can comprise any oxidizing agent known to one of skill in the art. In further embodiments, the reactant comprises one or more oxidizing agent.

In specific embodiments, the reactant is a reducing agent comprising a nitrogen source. In one or more embodiments, the reducing agent is selected from one or more of 1,1-dimethylhydrazine (DMH), alkyl amine, hydrazine, alkyl hydrazine, allyl hydrazine, ammonia (NH₃), and nitrous oxide (N₂O). In some embodiments, the alkyl amine is selected from one or more of tert-butyl amine (tBuNH₂), isopropyl amine (iPrNH₂), ethylamine (CH₃CH₂NH₂), diethylamine ((CH₃CH₂)₂NH), or butyl amine (BuNH₂). In some embodiments, the reactant comprises one or more of compounds with the formula R′NH₂, R′₂NH, R′₃N, R′₂SiNH₂, (R′₃Si)₂NH, (R′₃Si)₃N; where each R′ is independently H or an alkyl group having 1-12 carbon atoms. In some embodiments, the alkyl amine consists essentially of one or more of tert-butyl amine (tBuNH₂), isopropyl amine (iPrNH₂), ethylamine (CH₃CH₂NH₂), diethylamine ((CH₃CH₂)₂NH), butyl amine (BuNH₂).

In other embodiments, the reactant is an oxidizing agent selected from one or more of oxygen (O₂), ozone (O₃), hydrogen peroxide (H₂O₂), water (H₂O), and an oxaziridine.

In some embodiments, the oxidant comprises an oxaziridine. In some embodiments, the oxaziridine comprises a compound with the general formula:

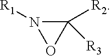

where R₁, R₂ and R₃ are independently selected from H, SO₂NO₂, CN, C₁-C₈ alkyl, C₁-C₈ perfluoroalkyl, pyridine, aryl, substituted aryl, perfluoroaryl, SO₂—NO₂ substituted aryl, or R₂ and R₃ are combined to form a carbonyl. In some embodiments, R₁, R₂ and R₃ are independently selected from C₁-C₆ alkyl, C1-C6 perfluoroalkyl, C1-C4 alkyl, or C1-C6 perfluoroalkyl. In one or more embodiments, a non-limiting collection of exemplary oxaziridines includes:

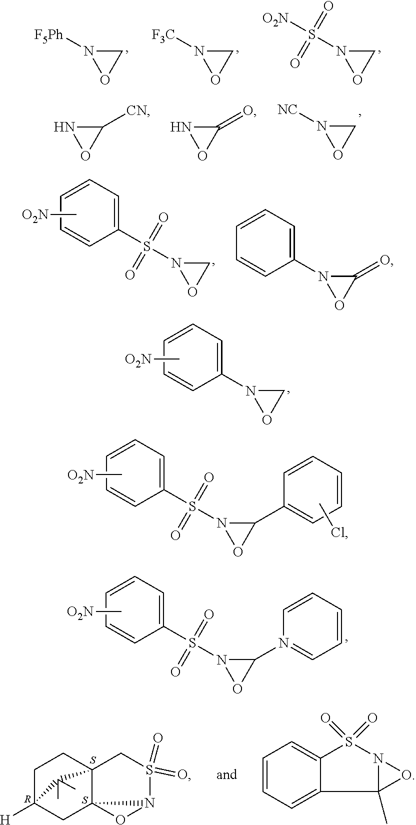

In some embodiments, when R₂ and R₃ are H, R₁ is an electron withdrawing group. In some embodiments, the electron withdrawing group is —CN or —SO₂NO₂.

In specific embodiments, the oxaziridine comprises one or more of:

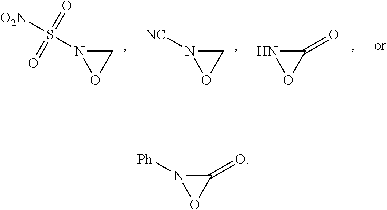

In some embodiments, the oxaziridine is bicyclic. In some embodiments, the oxaziridine comprises one or more of:

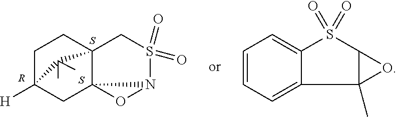

In some embodiments, the oxidant comprises a P/S/N oxide. As used in this regard, a “P/S/N oxide” refers to the genus of oxides comprising P-oxides, S-oxides and N-oxides. In some embodiments, the P/S/N oxide comprises a compound with the general formula:

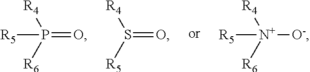

where R₄, R₅ and R₆ are independently selected from H, C₁-C₈ alkyl, or aryl, and R₄ and R₅ may join to form a three to six membered ring including at least one P, S or N heteroatom. In some embodiments, R₄, R₅ and R₆ are independently selected from C₁-C₆ alkyl, or C₁-C₄ alkyl.

In some embodiments, the P/S/N oxide comprises a P-oxide. In some embodiments, the P-oxide comprises one or more of H₃PO, (CH₃)₃PO, (C₂H₅)₃PO, MPPO (3-methyl-1-phenyl-2-phospholene 1-oxide), 3-methyl-1-phenyl-3-phospholene 1-oxide, neopentylene phosphite (5,5-Dimethyl-1,3,2-dioxaphosphinane 2-oxide), HASPO-1 (4,4,5,5-Tetramethyl-1,3,2-dioxaphospholane 2-oxide), 2-Methyl-4,4,5,5-tetramethyl-1,3,2-dioxaphospholan-2-one, ordiphenylphosphine oxide.

In some embodiments, the P/S/N oxide comprises a S-oxide. In some embodiments, the S-oxide comprises one or more of H₂SO, or MPSO (methyl phenyl sulfoxide).

In some embodiments, the P/S/N oxide comprises an N-oxide. In some embodiments, the N-oxide comprises one or more of H₃N→O, trimethylamine n-oxide, pyridine-n-oxide, TEMPO ((2,2,6,6-Tetramethylpiperidin-1-yl)oxyl), N-hydroxyphthalimide, or 4-methylmorpholine n-oxide.

At operation 118, the processing chamber is optionally purged after exposure to the reactant. Purging the processing chamber in operation 118 can be the same process or different process than the purge in operation 114. Purging the processing chamber, portion of the processing chamber, area adjacent the substrate surface, etc., removes unreacted reactants, reaction products, and by-products from the area adjacent the substrate surface.

At decision 120, the thickness of the deposited film, or number of cycles of silicon-chalcogen precursor and reactant is considered. If the deposited film has reached a predetermined thickness or a predetermined number of process cycles have been performed, the method 100 moves to an optional post-processing operation 130. In some embodiments, the process cycle comprises sequential exposure of the substrate to the silicon-chalcogen precursor, purge gas, reactant and purge gas. If the thickness of the deposited film or the number of process cycles has not reached the predetermined threshold, the method 100 returns to operation 110 to expose the substrate surface to the silicon-chalcogen precursor again in operation 112 and continuing.

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited film. In some embodiments, the optional post-processing operation 130 comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film. In one or more embodiments, annealing can also with performed with a gas under plasma. In one or more embodiments, the annealing temperature may be lower with plasma.

In one or more embodiments, the plasma of the optional post-processing operation 130 comprises one or more of nitrogen (N₂), argon (Ar), helium (He), hydrogen (H₂), carbon monoxide (CO), carbon dioxide (CO₂) methane (CH₄), and ammonia (NH₃). In some embodiments, the plasma is a remote plasma. In other embodiments, the plasma is a direct plasma.

In one or more embodiments, the plasma of the optional post-processing operation 130 may be generated remotely or within the processing chamber. In one or more embodiments, the plasma is an inductively coupled plasma (ICP) or a conductively coupled plasma (CCP). Any suitable power can be used depending on, for example, the reactants, or the other process conditions. In some embodiments, the plasma is generated with a plasma power in the range of about 10 W to about 3000 W. In some embodiments, the plasma is generated with a plasma power less than or equal to about 3000 W, less than or equal to about 2000 W, less than or equal to about 1000 W, less than or equal to about 500 W, or less than or equal to about 250 W.

The method 100 can be performed at any suitable temperature depending on, for example, the silicon-chalcogen precursor, reactant or thermal budget of the device. In one or more embodiments, the use of high temperature processing may be undesirable for temperature-sensitive substrates, such as logic devices. In a particular embodiment, the method 100 is a plasma-free deposition method. In some embodiments, the method 100 is performed at a low temperature. In some embodiments, the method is performed at a temperature in a range of from 20° C. to 650° C. In some embodiments, the method 100 is performed at low temperature without the use of plasma.

In some embodiments, exposure to the silicon-chalcogen precursor (operation 112) and the reactant (operation 116) occur at the same temperature. In some embodiments, the substrate is maintained at a temperature in a range of from 20° C. to 650° C., from 20° C. to 500° C., from 20° C. to 400° C., from 20° C. to 300° C., from 50° C. to 650° C., from 50° C. to 550° C., from 50° C. to 500° C., from 50° C. to 400° C., from 50° C. to 300° C., from 100° C. to 650° C., from 100° C. to 550° C., from 100° C. to 500° C., from 100° C. to 400° C. or from 100° C. to 300° C. In some embodiments, the substrate is maintained at a temperature in a range of from 20° C. to <650° C., from 20° C. to <500° C., from 20° C. to <400° C., from 20° C. to <300° C., from 50° C. to <650° C., from 50° C. to <550° C., from 50° C. to <500° C., from 50° C. to <400° C., from 50° C. to <300° C., from 100° C. to <650° C., from 100° C. to <550° C., from 100° C. to <500° C., from 100° C. to <400° C. or from 100° C. to <300° C.

In some embodiments, exposure to the silicon-chalcogen precursor (operation 112) occurs at a different temperature than the exposure to the reactant (operation 116). In some embodiments, the substrate is exposed to the silicon-chalcogen precursor (operation 112) at a first temperature in a range of from 20° C. to 650° C., from 20° C. to 500° C., from 20° C. to 400° C., from 20° C. to 300° C., from 50° C. to 650° C., from 50° C. to 550° C., from 50° C. to 500° C., from 50° C. to 400° C., from 50° C. to 300° C., from 100° C. to 650° C., from 100° C. to 550° C., from 100° C. to 500° C., from 100° C. to 400° C. or from 100° C. to 300° C. In some embodiments, the substrate is exposed to the silicon-chalcogen precursor (operation 112) at a first temperature in a range of from 20° C. to <650° C., from 20° C. to <500° C., from 20° C. to <400° C., from 20° C. to <300° C., from 50° C. to <650° C., from 50° C. to <550° C., from 50° C. to <500° C., from 50° C. to <400° C., from 50° C. to <300° C., from 100° C. to <650° C., from 100° C. to <550° C., from 100° C. to <500° C., from 100° C. to <400° C. or from 100° C. to <300° C. In some embodiments, the reactant is reacted with the precursor film (operation 116) at a temperature in a range of from 20° C. to 650° C., from 20° C. to 500° C., from 20° C. to 400° C., from 20° C. to 300° C., from 50° C. to 650° C., from 50° C. to 550° C., from 50° C. to 500° C., from 50° C. to 400° C., from 50° C. to 300° C., from 100° C. to 650° C., from 100° C. to 550° C., from 100° C. to 500° C., from 100° C. to 400° C. or from 100° C. to 300° C. In some embodiments, the reactant is reacted with the precursor film (operation 116) at a temperature in a range of from 20° C. to <650° C., from 20° C. to <500° C., from 20° C. to <400° C., from 20° C. to <300° C., from 50° C. to <650° C., from 50° C. to <550° C., from 50° C. to <500° C., from 50° C. to <400° C., from 50° C. to <300° C., from 100° C. to <650° C., from 100° C. to <550° C., from 100° C. to <500° C., from 100° C. to <400° C. or from 100° C. to <300° C.

In the embodiment illustrated in FIG. 1, at deposition operation 110 the substrate (or substrate surface) is exposed to the silicon-chalcogen precursor and the reactant sequentially. In another, un-illustrated, embodiment, the substrate (or substrate surface) is exposed to the silicon-chalcogen precursor and the reactant simultaneously in a CVD reaction. In a CVD reaction, the substrate (or substrate surface) can be exposed to a gaseous mixture of the silicon-chalcogen precursor and reactant to deposit a silicon nitride (SiₓN_{y}) film and/or a silicon oxide (SiOₓ) film having a predetermined thickness. In the CVD reaction, the silicon nitride (SiₓN_{y}) film, the silicon oxide (SiOₓ) film, and/or the silicon oxynitride (SiOₓN_{z}) film can be deposited in one exposure to the mixed reactive gas or can be multiple exposures to the mixed reactive gas with purges between.

The deposition operation 110 can be repeated to form a silicon nitride (SiₓN_{y}) film, a silicon oxide (SiOₓ) film, and/or a silicon oxynitride (SiOₓN_{z}) film having a predetermined thickness. In some embodiments, the deposition operation 110 is repeated to provide the silicon nitride (SiₓN_{y}) film, the silicon oxide (SiOₓ) film, and/or the silicon oxynitride (SiOₓN_{z}) film having a thickness in the range of from 0.3 nm to 3000 nm, from 0.3 nm to 2000 nm, from 0.3 nm to 1000 nm, from 0.3 nm to 500 nm, from 0.3 nm to 400 nm, from 0.3 nm to 300 nm, from 0.3 nm to 200 nm, from 0.3 nm to 100 nm, from 1 nm to 3000 nm, from 1 nm to 2000 nm, from 1 nm to 1000 nm, from 1 nm to 500 nm, from 1 nm to 400 nm, from 1 nm to 300 nm, from 1 nm to 200 nm or from 1 nm to 100 nm.

One or more embodiments of the disclosure are directed to methods of depositing silicon nitride (SiₓN_{y}) films, silicon oxide (SiOₓ) films, and/or silicon oxynitride (SiOₓN_{z}) filmₛ in high aspect ratio features, e.g., in memory devices or logic devices, including, but not limited to, 3D NAND, DRAM, 3D DRAM, FinFET, GAA, and the like. A high aspect ratio feature is a trench, via or pillar having a height:width ratio greater than or equal to about 10, 20, or 50, or more. In some embodiments, the silicon nitride (SiₓN_{y}) film and/or the silicon oxide (SiOₓ) film is deposited conformally on the high aspect ratio feature. As used in this manner, a conformal film has a thickness near the top of the feature that is in the range of about 80-120% of the thickness at the bottom of the feature.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. The exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Preparation of Si(SCH₂CF₃)₄

### Thiolate Generation

Sodium (Na) (washed with dry hexane and oxides removed) was charged into 3-necked flask (250 ml). Dry 1,2-dimethoxyethane (DME) (40 ml) was added under argon (Ar) and stirred. Thiol (7.28 ml-10% excess) was added into an additional funnel under Ar, diluted with DME (10 ml). The thiol solution was added dropwise into a reaction mixture in the presence of an ice-bath. To prevent loss of thiol from reaction heat evolution, it was ensured that the addition rate did not cause reaction temperature increment.

Additional DME (10 ml) was added through the addition funnel after thiol addition was complete. Na(thiolate) was relatively soluble in DME and therefore minimal precipitate was observed. Reaction mixture was stirred for 2.5-3 h until Na was fully reacted.

### Si Addition

DME (3 ml) was added into the addition funnel. SiCl₄ (1.9 ml) was charged into an addition funnel and the SiCl₄ solution was added dropwise into the reaction mixture. The reaction was exothermic, and the rate of addition was controlled so as not to cause the reaction mixture to reflux. White precipitate was observed immediately on addition. After addition was completed, DME (5 ml) was added. Reaction mixture was refluxed for 12 h.

The reaction mixture was allowed to cool. The reaction mixture was filtered under Ar through a sintered glass frite (M) set up by cannula transfer. The reaction flask was washed with dry diethyl ether (10 ml), and the solvent was removed under vacuum to give a pale-yellow oil.

The DME was completely removed. Dry ether was added to precipitate any Na salts overnight. The mixture was filtered through a sintered glass frite (F) set up by cannula transfer and washed with minimal dry ether. The solvent was removed to give a pale-yellow oil (sometimes reddish-brown).

The oil was further purified by vacuum distillation to give a colorless oil (b.p. 70° C. at 0.9-0.97 mbar). B.p. of Si(SCH₂CF₃)₄ approx. 255° C. at s.t.p.

Crystals may be obtained by cooling (m.p. approx. 22° C.).

NMR (ppm): ²⁹Si (99 MHz, CDCl₃): 38 (s); ¹³C{¹H} (125 MHz, CDCl₃): 124.6 (q, CF₃. J=275 Hz), 30.7 (q, CH₂, J=35 Hz); ¹⁹F (470 MHz, CDCl₃): −66.8 (t, CF₃, J=9.4 Hz); ¹H (500 MHz, CDCl₃): 3.36 (q, CH₂, J=10 Hz);

MS (EI): 488.1 (M)

IR (cm⁻¹): 3009 (m), 2995 (m), 1417 (m), 1313 (s), 1259 (s), 1241 (s), 1131 (vs), 1077 (vs), 869 (m), 844 (m), 761 (m), 636 (m), 542 (m)

### Example 2: Preparation of Si(OSO₂CF₃)₄

Ag[SO₃CF₃](6 g, 23.4 mmol) was charged into a 100 ml Schlenk flask. Dry dichloromethane (DCM) (17 ml) was added into the flask under Ar atmosphere. The beige suspension was stirred and cooled with an ice-water bath before SiBr₄ (0.7 ml, 5.58 mmol) was added slowly into the suspension (note the reaction was slightly exothermic). The reaction mixture was stirred for 24 h with the flask protected from light with foil. The beige suspension slowly turned pale-yellow overtime.

The pale-yellow suspension was filtered through an M-grade glass frite fitted with 2 layers of filter paper in the glovebox. The AgBr salt was washed several times with DCM (3×5 ml) and the colorless filtrate collected. The filtrate solvent was removed under reduced pressure during which time white solids start to precipitate out as the filtrate concentration increases and cooling is occurring. As DCM was mostly removed, the solids melted to give a very pale-yellow oil. The oil was Si(OSO₂CF₃)₄ which had a melting point between −10° C. to 5° C.

NMR (ppm): ²⁹Si (99 MHz, CDCl₃): −121 (s); ¹³C{¹H} (125 MHz, CDCl₃): 118 (q, CF₃. J=317.5 Hz); ¹⁹F (470 MHz, CDCl₃): −74.3 (s)

### Comparative Example 3

A thiosilane having the formula Si(SCH₂CH₃)₄ was synthesized in tetrahydrofuran (THF) from its corresponding starting halosilane via nucleophilic substitution of the halogen atom with thiolate in the presence of sodium hydride (NaH) as a base. The one-pot synthesis resulted in complete conversion to the thiosilane product. During the synthesis, a side product sodium halide was produced that was separated out from the thiosilane product via filtration. Purification was carried out by vacuum distillation. A colorless oil was obtained (bp 95-97° C., 0.5 mbar pressure) approx. 300° C. at s.t.p.

### Comparative Example 4

A thiosilane having the formula Si(SPh)₄ was synthesized in tetrahydrofuran (THF) from its corresponding starting halosilane via nucleophilic substitution of the halogen atom with thiolate in the presence of sodium hydride (NaH) as a base. The one-pot synthesis resulted in complete conversion to the thiosilane product. During the synthesis, a side product sodium halide was produced that was separated out from the thiosilane product via filtration. Further purification by recrystallization from tetrahydrofuran/hexanes mixture.

### Example 5: Atomic Layer Deposition of Chalcogen Containing Films

General procedure: A silicon substrate was placed in a processing chamber. A silicon-chalcogen precursor flowed into the processing chamber in an atmosphere of nitrogen (N₂) gas over the silicon substrate leaving a chalcogen-precursor terminated surface. Unreacted precursors and byproducts were then purged out of the chamber. Next, a co-reactant was then introduced into the chamber that reacted with the surface-bound chalcogen species. Again, excess co-reactant and byproducts were removed from the chamber. The resultant material on the substrate was a chalcogen-containing film.

TABLE 1

| | Silicon-chalcogen | | Film | |
|---|---|---|---|---|
| | precursor | Reactant | Formed | Reaction Outcome |
| A | Example 1 | piperazine | SiNₓ | Slow, Complete |
| B | Example 2 | piperazine | SiNₓ | Fast, Complete |
| C | Comparative Example 3 | piperazine | SINₓ | No reaction |
| D | Example 1 | aniline | SiNₓ | Slow, Complete |
| E | Example 2 | aniline | SiNₓ | Fast, Complete |
| F | Comparative Example 3 | aniline | SiNₓ | No reaction |
| G | Example 1 | DMSO | SiOₓ | Fast, Complete |
| H | Comparative Example 3 | DMSO | SiOₓ | Very slow, |
| | | | | Incomplete |
| I | Comparative Example 4 | DMSO | SiOₓ | Slow, Incomplete |
| J | Example 1 | TMSO | SiOₓ | Fast, Complete |
| K | Example 1 | TMANO | SiOₓ | Fast, Complete |
| L | Comparative Example 3 | TMANO | SiOₓ | Slow, Complete |

* Note:
dimethylsulfoxide (DMSO); tetramethylene sulfoxide (TMSO); trimethylamine N-oxide (TMANO)

### Example 6: DFT Calculations: Substituent Effect on Sulfur

TABLE 2

SiX₄ + NH₃ → X₃Si-NH₂ + H-X

| | Reaction Energy | Reaction Barrier |
|---|---|---|
| | (ΔG), | (ΔG^{≠}), |
| Precursor | kcal/mol | kcal/mol |
| SiCl₄ | −4.6 | 22.4 |
| Comparative Example 1 | −10.0 | 17.6 |
| [Si(SCH₂CF₃)₄] | | |
| Example 3 | −4.1 | 30.6 |
| [Si(SCH₂CH₃)₄] | | |

### Conclusions:

As illustrated in Table 1, for Examples A-F, the rate and completion of reaction indicates stronger electron withdrawing group (EWG) ligands result in faster and complete conversion of starting silicon-chalcogen precursor to SiNₓ.

As illustrated in Table 1, for Examples G-J, increasing the presence and strength of the electron withdrawing group (EWG) from the precursor of Comparative Example 3 and the precursor of Comparative Example 4 to the precursor of Example 1 results in a faster and higher conversion to silicon oxide (SiOₓ).

As illustrated in Table 1, for Examples K-L, the presence of electron withdrawing ligands increases the reaction rate with trimethylamine N-oxide (TMANO).

As illustrated in Table 2, the reaction barrier value for Example 1 having an electron withdrawing group (EWG) is lower than that of Comparative Example 3. For sulfur containing precursors, electron withdrawing groups decrease the barrier compared to sulfur containing precursors that do not have an electron withdrawing group.

Spatially relative terms, such as “beneath,” “below,” “lower,” “above,” “upper” and the like, may be used herein for ease of description to describe one element or feature's relationship to another element(s) or feature(s) as illustrated in the FIGURES. It will be understood that the spatially relative terms are intended to encompass different orientations of the device in use or operation in addition to the orientation depicted in the FIGURES. For example, if the device in the FIGURES is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film, the method comprising:
exposing a substrate to a silicon-chalcogen precursor comprising a chalcogen and an electron withdrawing group; and
exposing the substrate to a reactant to form a silicon nitride (SiₓN_{y}) film, a silicon oxide (SiOₓ) film, or a silicon oxynitride (SiOₓN_{z}) film on the substrate.

2. The method of claim 1, wherein the chalcogen comprises one or more of a thiosilane, a selenosilane, and a tellurosilane.

3. The method of claim 1, wherein the electron withdrawing group comprises one or more of fluorinated or perfluoronated alkyl groups having the general formula (II) CₙF₂ₙ₊₁, wherein n is an integer in a range of from 1 to 10, fluorinated or perfluoronated alkyl groups having the general formula (III) CnH₂ₙCF₃, wherein n is an integer in a range of from 1 to 10, nitro (NO₂), nitrile (CN), nitroso (NO), and SO₂CF₃.

4. The method of claim 1, wherein the silicon-chalcogen precursor comprises a structure of general formula (I) 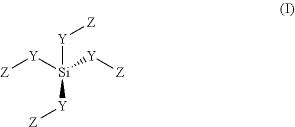
wherein Y is selected from the group consisting of oxygen (O), sulfur (S), selenium (Se), and tellurium (Te), and Z is an electron withdrawing group. In one or more embodiments, Z is selected from the group consisting of fluorinated or perfluoronated alkyl groups having the general formula (II) CₙF₂ₙ₊₁, wherein n is an integer in a range of from 1 to 10, fluorinated or perfluoronated alkyl groups having the general formula (III) CnH₂ₙCF₃, wherein n is an integer in a range of from 1 to 10, nitro (NO₂), nitrile (CN), nitroso (NO), and SO₂CF₃.

5. The method of claim 1, wherein the silicon-chalcogen precursor comprises one or more of —SCₙF₂ₙ₊₁, wherein n is an integer in a range of from 1 to 10, SCₙH₂ₙCF₃, wherein n is an integer in a range of from 1 to 10, —SNO₂, —SCN, SSO₂CF₃, —OCₙF₂ₙ₊₁, wherein n is an integer in a range of from 1 to 10, OCₙH₂ₙCF₃, wherein n is an integer in a range of from 1 to 10, —ONO₂, —OCN, OSO₂CF₃, —SeCₙF₂ₙ₊₁, wherein n is an integer in a range of from 1 to 10, SeCₙH₂ₙCF₃, wherein n is an integer in a range of from 1 to 10, —SeNO₂, —SeCN, —SeSO₂CF₃, —TeCₙF₂ₙ₊₁, wherein n is an integer in a range of from 1 to 10, TeCₙH₂ₙCF₃, wherein n is an integer in a range of from 1 to 10, —TeNO₂, —TeCN, and TeSO₂CF₃.

6. The method of claim 1, wherein the substrate is exposed to the silicon-chalcogen precursor at a temperature in a range of from 100° C. to 400° C.

7. The method of claim 1, wherein the method comprises one or more of chemical vapor deposition or atomic layer deposition.

8. The method of claim 7, wherein the substrate is exposed to the silicon-chalcogen precursor and the reactant simultaneously.

9. The method of claim 7, wherein the substrate is exposed to the silicon-chalcogen precursor and the reactant sequentially.

10. The method of claim 1, further comprising purging the substrate of the silicon-chalcogen precursor prior to exposing the substrate to the reactant.

11. The method of claim 10, wherein purging comprises one or more of applying a vacuum or flowing a purge gas over the substrate.

12. The method of claim 11, wherein the purge gas comprises one or more of nitrogen (N₂), helium (He), and argon (Ar).

13. The method of claim 1, wherein the reactant comprises one or more of dimethylhydrazine (DMH), alkyl amine, hydrazine, alkyl hydrazine, allyl hydrazine, ammonia (NH₃), oxygen (O₂), ozone, hydrogen peroxide (H₂O₂), water (H₂O), and an oxaziridine.

14. The method of claim 1, wherein the film is substantially free of halogen.

15. A method of depositing a halogen-free film, the method comprising:
forming one or more of a silicon nitride (SiₓN_{y}) film, a silicon oxide (SiOₓ) film, or a silicon oxynitride (SiOₓN_{z}) film in a process cycle comprising sequential exposure of a substrate to a silicon-chalcogen precursor, purge gas, a reactant, and purge gas, the silicon-chalcogen precursor comprising a chalcogen and an electron withdrawing group.

16. The method of claim 15, wherein the chalcogen comprises one or more of a thiosilane, a selenosilane, and a tellurosilane.

17. The method of claim 15, wherein the electron withdrawing group comprises one or more of fluorinated or perfluoronated alkyl groups having the general formula (II) CₙF₂ₙ₊₁, wherein n is an integer in a range of from 1 to 10, fluorinated or perfluoronated alkyl groups having the general formula (III) CnH₂ₙCF₃, wherein n is an integer in a range of from 1 to 10, nitro (N₀₂), nitrile (CN), nitroso (NO), and SO₂CF₃.

18. The method of claim 15, wherein the silicon-chalcogen precursor comprises a structure of general formula (I) 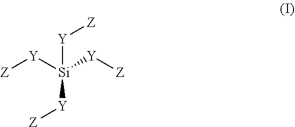
wherein Y is selected from the group consisting of oxygen (O), sulfur (S), selenium (Se), and tellurium (Te), and Z is an electron withdrawing group. In one or more embodiments, Z is selected from the group consisting of fluorinated or perfluoronated alkyl groups having the general formula (II) CₙF₂ₙ₊₁, wherein n is an integer in a range of from 1 to 10, fluorinated or perfluoronated alkyl groups having the general formula (III) CnH₂ₙCF₃, wherein n is an integer in a range of from 1 to 10, nitro (NO₂), nitrile (CN), nitroso (NO), and SO₂CF₃.

19. The method of claim 15, wherein the silicon-chalcogen precursor comprises one or more of —SCₙF₂ₙ₊₁, wherein n is an integer in a range of from 1 to 10, SCₙH₂ₙCF₃, wherein n is an integer in a range of from 1 to 10, —SNO₂, —SCN, SSO₂CF₃, —OCₙF₂ₙ₊₁, wherein n is an integer in a range of from 1 to 10, OCₙH₂ₙCF₃, wherein n is an integer in a range of from 1 to 10, —ONO₂, —OCN, OSO₂CF₃, —SeCₙF₂ₙ₊₁, wherein n is an integer in a range of from 1 to 10, SeCₙH₂ₙCF₃, wherein n is an integer in a range of from 1 to 10, —SeNO₂, —SeCN, —SeSO₂CF₃, —TeCₙF₂ₙ₊₁, wherein n is an integer in a range of from 1 to 10, TeCₙH₂ₙCF₃, wherein n is an integer in a range of from 1 to 10, —TeNO₂, —TeCN, and TeSO₂CF₃.

20. The method of claim 19, wherein the reactant comprises one or more of dimethylhydrazine (DMH), alkyl amine, hydrazine, alkyl hydrazine, allyl hydrazine, ammonia (NH₃), oxygen (O₂), ozone, hydrogen peroxide (H₂O₂), water (H₂O), and an oxaziridine.
